(19) United States
(12) Patent Application Publication
(10) Pub. No.: US 2006/0007658 A1
(43) Pub. Date: Jan. 12, 2006

(54) Heat dissipation apparatus

(75) Inventors: Ming-Te Chuang, Taoyuan Hsien (TW); Chi-Feng Lin, Taoyuan Hsien (TW); Chin-Ming Chen, Taoyuan Hsien (TW)

Correspondence Address: BIRCH STEWART KOLASCH & BIRCH, PO BOX 747, FALLS CHURCH, VA, 22040-0747, US

(73) Assignee: Delta Electronics, Inc.

(21) Appl. No.: 11/007,193

(22) Filed: Dec. 9, 2004

(30) Foreign Application Priority Data
Jul. 9, 2004 (TW) 93120593

(51) Int. Cl. H05K 7/20

(52) U.S. Cl. 361/704

(57) ABSTRACT

A heat dissipation apparatus. The heat dissipation apparatus includes a base and a support member. The support member has an opening and at least one protruding part surrounding the opening. The support member is connected with the base in a predetermined site by the protruding parts. When the base passes through the opening and the protruding parts are disposed in the predetermined site, the protruding parts become deformed to be engaged with the base by a force. The protruding parts and the support member may be integrally formed. Alternately, the base may comprise a groove in the predetermined site for allowing the protruding parts be inserted into the groove. The protruding parts substantially protrude inwardly into the opening so that the support member is engaged with the base when the protruding parts are inserted into the groove.

This Non-provisional application claims priority under U.S.C.§ 119 (a) on Patent Application No(s). 093120593 filed in Taiwan, Republic of China on Jul. 9, 2004, the entire contents of which are hereby incorporated by reference

### BACKGROUND

The invention relates to a heat dissipation apparatus and more particularly, to a heat dissipation apparatus with an improved support member.

Precision electrical components can generate excess heat. To accelerated dissipate heat from the electrical components, a fan and a heat sink are typically disposed on a heat source. Further, a heat pipe can transfer heat away without using power. Heat pipes are widely used for heat dissipation without requiring power or excess space.

FIGS. 1A and 1B show a conventional heat dissipation apparatus 10, applicable to a fan, disposition on a heat source such as CPU, transistor, or other environments. In FIG. 1A, the heat dissipation apparatus 10 comprises a heat sink 11, a support 13, and a base 15. The base 15 has a flange 151 at the bottom. The support 13 has an opening 131 and encircles the base 15 via the opening 131, supported by the flange 151. The heat sink 11 has a passage 111 corresponding to the base 15 allowing fixing therebetween. FIG. 1B shows the assembled heat dissipation apparatus, in which the flange 151 supports the support 13, and the support 13 is sandwiched between the heat sink 11 and the flange 151.

After assembly, the heat dissipation apparatus is disposed on a heat source, for example a CPU. The bottom of the base 15 contacts the surface of the CPU, whereby heat from the CPU passes through the base 15 to the heat sink 11 for dissipation.

FIG. 1C is a cross section of the assembled heat dissipation apparatus. The base 15 with the flange 151 supports the support 13 to prevent separation therefrom. The base may be a copper heat pipe or a solid copper bar, formed on a lathe to create the flange, using extra material, generating waste, and increasing costs. Further, the flange increases overall volume of the heat dissipation apparatus.

### SUMMARY

Accordingly, a heat dissipation apparatus is disclosed, comprising a base and a support member. The support member has an opening and at least one protruding part surrounded the opening. The support member is connected with the base in a predetermined site by the protruding parts. When the base passes through the opening and the protruding parts are disposed in the predetermined site, the protruding parts become deformed to be engaged with the base by a force. The protruding parts and the support member may be integrally formed. Alternately, the base may comprise a groove in a predetermined site for allowing the protruding parts be inserted into the groove. The protruding parts substantially protrude inwardly into the opening so that the support member is engaged with the base when the protruding parts are inserted into the groove. The heat dissipation apparatus may further comprise a heat sink for allowing the base be mounted therein.

Another heat dissipation apparatus is disclosed, comprising a base, a heat sink and a support member. The heat sink is disposed around the base, and the support member contacts and supports the heat sink. The support member has an opening and at least one protruding part surrounding the opening. The support member is connected with the base in a predetermined site by the protruding parts. When the base passes through the opening and the protruding parts are disposed in the predetermined site, the protruding parts become deformed to be engaged with the base by a force. The base may further comprise a groove in a predetermined site for allowing the protruding parts be inserted into the groove, securing the support member on the base.

Other objects, features, and advantages of the invention will become apparent from the following detailed description of the preferred but non-limiting embodiments. The following description is made with reference to the accompanying drawings.

### DESCRIPTION OF THE DRAWINGS

FIG. 1A is a schematic diagram of a conventional heat dissipation apparatus;

FIG. 1B is a schematic diagram of the assembled heat dissipation apparatus according to FIG. 1A;

FIG. 1C is a cross section of the assembled heat dissipation apparatus according to FIG. 1A;

FIG. 2A is a schematic diagram of a heat dissipation apparatus of embodiments of the invention;

FIG. 2B is a cross section of the connected heat dissipation apparatus according to FIG. 2A;

FIG. 2C is a cross section of the assembled heat dissipation apparatus according to FIG. 2A;

FIG. 3A is a schematic diagram of another heat dissipation apparatus of embodiments of the invention;

FIG. 3B is a cross section of the connected heat dissipation apparatus according to FIG. 3A; and

FIG. 3C is a cross section of the assembled heat dissipation apparatus according to FIG. 3A.

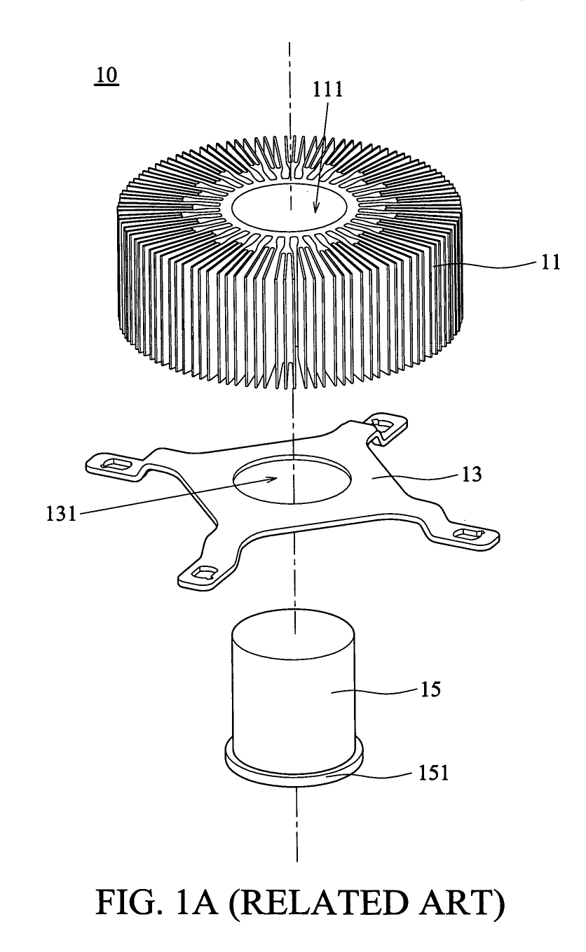

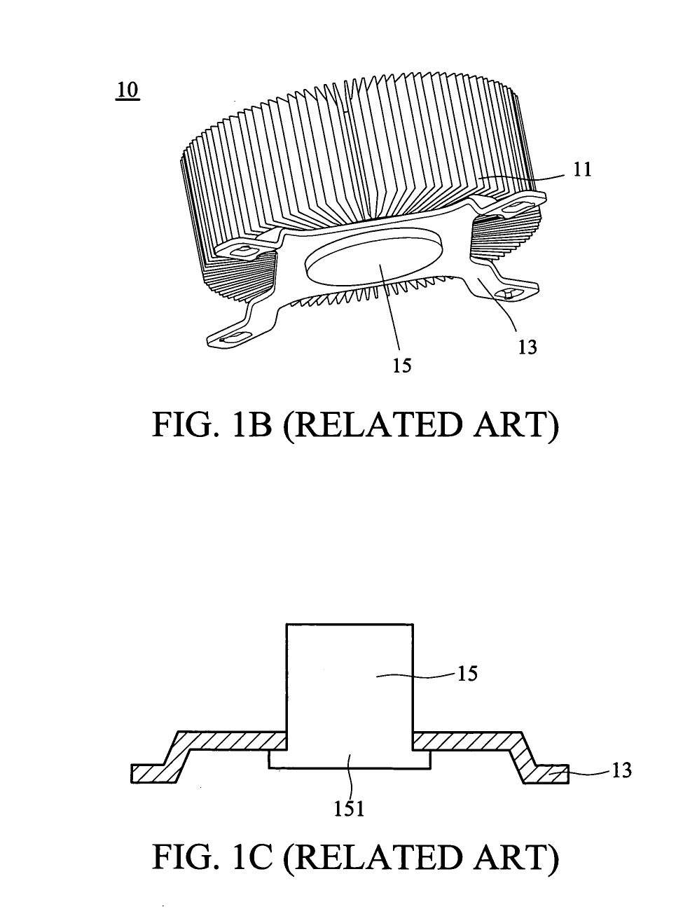

### DETAILED DESCRIPTION

### First Example

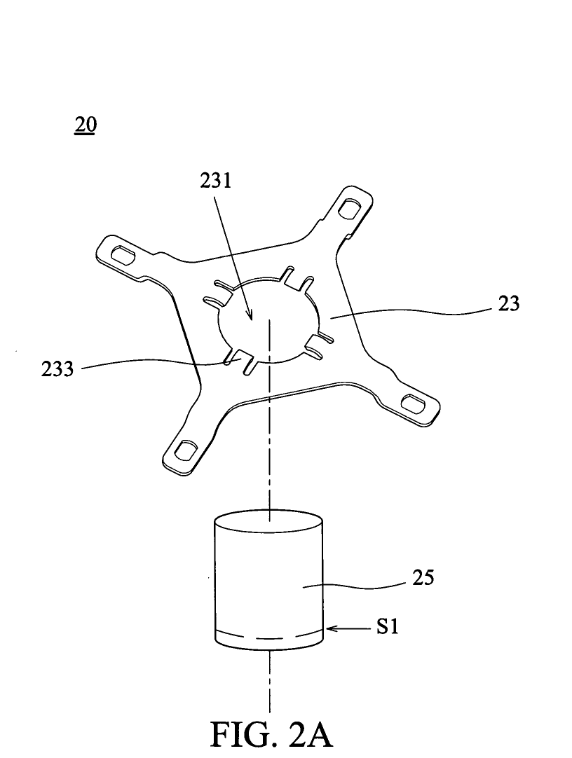

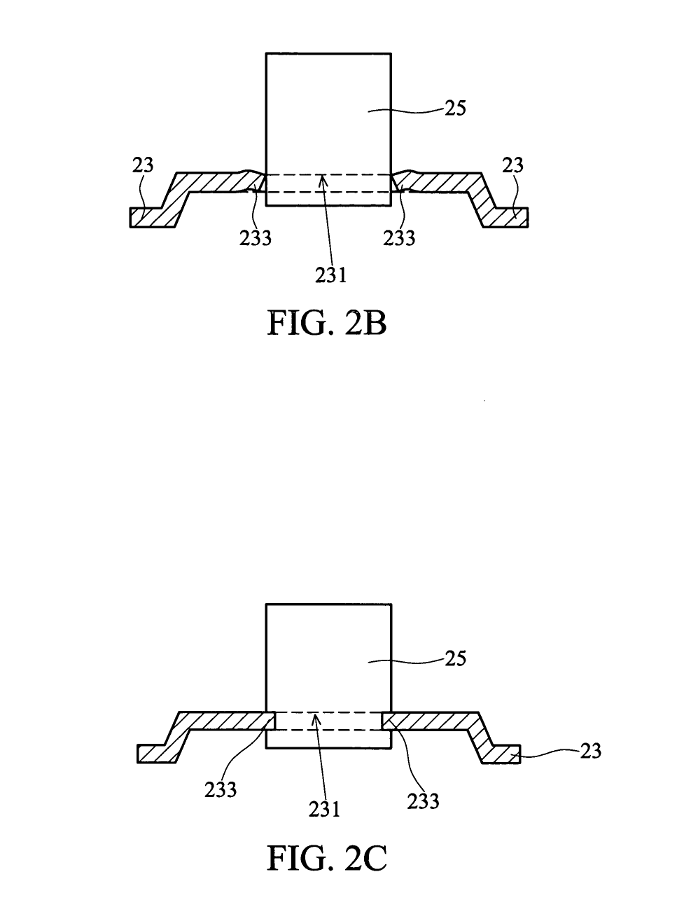

FIGS. 2A, 2B, and 2C show a heat dissipation apparatus of the invention. FIG. 2A is a schematic diagram of the heat dissipation apparatus and FIGS. 2B and 2C are cross sections thereof. The heat dissipation apparatus 20 of the first embodiment of the invention comprises a base 25, a heat sink (not shown), and a support member 23.

The support member 23 has an opening 231 and at least one protruding part 233. In this embodiment, the support member 23 has four protruding parts evenly disposed and surrounding the circumference of the opening 231. The protruding parts 233 are curved, and the tops thereof are higher than the surface of the support member 23. Length of the protruding parts 233 is not limited, such that the protruding parts 233 may abut the base 25, protrude from the opening 231, or reduce from the opening 231. Here, the protruding parts 233 abut the base 25, as shown in FIG. 2B.

The support member 23 is connected with the base 25 after passing through the opening 231. When the base 25 passes through the opening 231 and the protruding parts 233 reach a predetermined site S1, the protruding parts 233 become deformed to be engaged with the base 25 by a force, enabling insertion thereof into the base 25 to connect therewith, and allowing the support member 23 to tight fit with the base 25, as shown in FIG. 2C.

The heat sink (not shown) preferably has a passage corresponding to the base 25. After the support member 23 is assembled with the base 25, the heat sink is disposed around the base 25 via the passage. The heat sink may be connected with the base 25 by thermal expansion and contraction, by spreading adhesives between the base 25 and the heat sink, or by soldering, increasing stability of connection between the base 25 and the heat sink. Furthermore, the bottom of the heat sink contacts the support member 23, such that the support member 23 supports the heat sink. Preferably, a fan is further applied in order to improve heat dissipation.

### Second Example

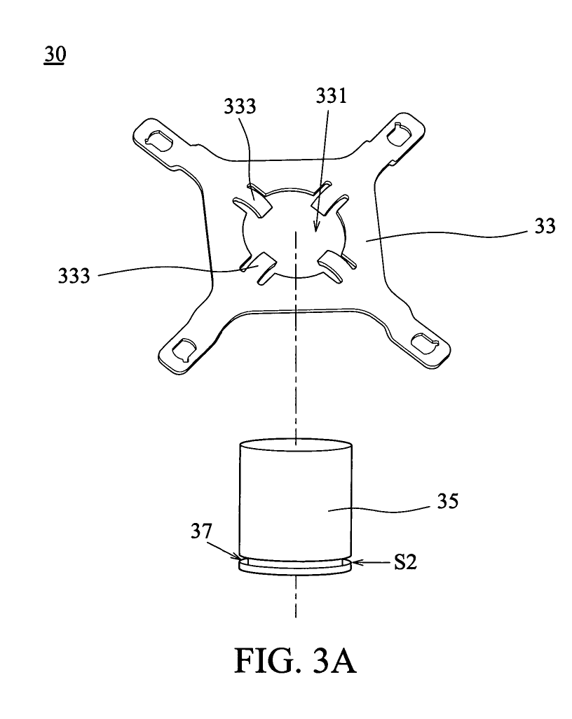

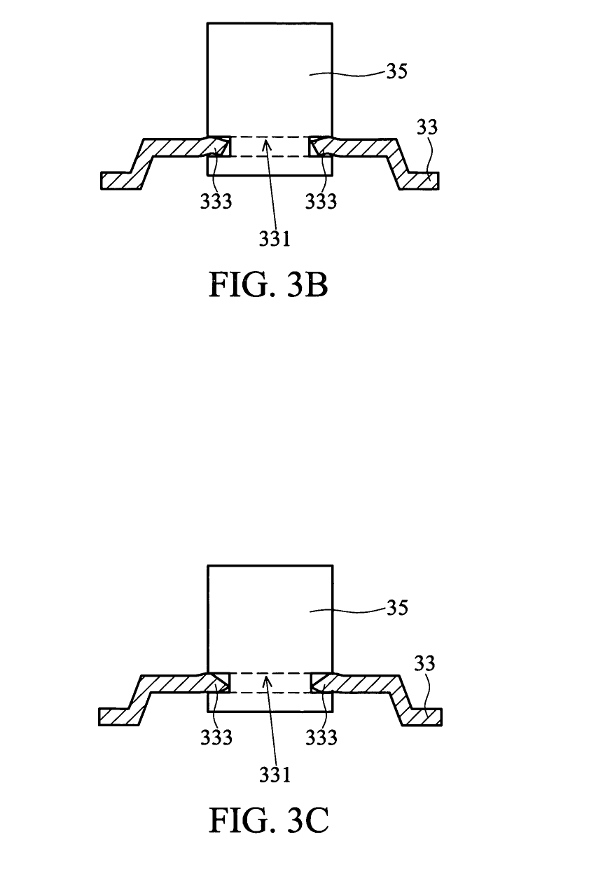

FIGS. 3A, 3B, and 3C show another heat dissipation apparatus. FIG. 3A is a schematic diagram of the heat dissipation apparatus and FIGS. 3B and 3C are cross section of the heat dissipation apparatus. The heat dissipation apparatus 30 comprises a base 35, a heat sink (not shown), and a support member 33.

The base 35 comprises a circular groove 37 located in a predetermined site S2. The support member 33 has an opening 331 and at least one protruding part 333. In this embodiment, the support member 33 has four protruding parts evenly disposed and surrounding the circumference of the opening 331.

In FIGS. 3A and 3B, the protruding parts 333 are curved and the tops thereof are higher than the surface of the support member 33. Also, the protruding parts 333 substantially protrude inwardly into the opening 331 so that the curved protruding parts 333 can be contracted by force to allow the base 35 passing through the opening 331 easily. When the support member 33 reaches the predetermined site S2 of the base 35, tension on the protruding parts 333 are released and the protruding parts 333 are inserted into the groove 37, so that the support member 33 is engaged with the base 35.

In FIG. 3C, force on the protruding parts 333 may further increase connection stability between the support member 33 and the base 35 by, for example, deforming the protruding parts 333, enabling insertion into the base 35, engaging with the groove 37, and allowing the support member 33 to tight fit with the base 35.

The heat sink (not shown) preferably has a passage corresponding to the base 35. After the support member 33 is assembled with the base 35, the heat sink is disposed around the base 35 via the passage. The heat sink may be connected with the base 35 by thermal expansion and contraction, by spreading adhesives between the base 35 and the heat sink, or by soldering, increasing stability of connection between the base 35 and the heat sink. Furthermore, the bottom of the heat sink contacts the support member 33, such that the support member 33 supports the heat sink. Preferably, a fan is further applied in order to improve heat dissipation.

The base of above-mentioned examples may be heat pipe or copper column. Or the material of the base may be plastic, metal, alloy, or nonmetallic materials. The assembled heat dissipation apparatus may be applied to a dissipation module for an electrical device which operates with generating heat, such as for a CPU, a transistor, or other components. The heat apparatus is variably shaped related to a shape of the electrical device.

The heat dissipation apparatus of the present invention having an improved supporting member reduces the procedure of using lathe to create the flange on the base so that there is no extra material waste and the production cost is saved. Also, forsaking the conventional design of the flange on the base, the overall volume of the heat dissipation apparatus can be more compact. However, the improved supporting member of the preferred embodiment is not limited thereto. For example, number, profile, and material of the protruding part are not limited, as long as the support member can be connected with the base by the protruding parts. Also, the protruding parts are preferably integrally formed with the support member for simplify assembly procedure. Further, the heat dissipation apparatus can operate and be associated with various heat sinks and fans.

While the invention has been described by way of example and in terms of preferred embodiment, it is to be understood that the invention is not limited thereto. On the contrary, it is intended to cover various modifications and similar arrangements as would be apparent to those skilled in the art. Therefore, the scope of the appended claims should be accorded the broadest interpretation so as to encompass all such modifications and similar arrangements.

What is claimed is:

1. A heat dissipation apparatus, comprising:
a base; and
a support member having an opening and at least one protruding part surrounding the opening;
wherein the support member is connected with the base in a predetermined site by the protruding parts.

2. The heat dissipation apparatus as claimed in claim 1, wherein the protruding part and the support member are integrally formed.

3. The heat dissipation apparatus as claimed in claim 1, wherein when the base passes through the opening and the protruding parts are disposed in the predetermined site, the protruding parts become deformed to be engaged with the base by a force.

4. The heat dissipation apparatus as claimed in claim 1, wherein the base comprises a groove in the predetermined site for allowing the protruding parts be inserted into the groove.

5. The heat dissipation apparatus as claimed in claim 4, wherein when the protruding parts are inserted into the groove, the protruding parts become deformed to be engaged with the base by a force.

6. The heat dissipation apparatus as claimed in claim 4, wherein the protruding parts substantially protrude inwardly into the opening so that the support member is engaged with the base when the protruding parts are inserted into the groove.

7. The heat dissipation apparatus as claimed in claim 1, further comprising a heat sink for allowing the base mounted therein.

8. The heat dissipation apparatus as claimed in claim 7, wherein the base and the heat sink are connected by welding.

9. The heat dissipation apparatus as claimed in claim 1, wherein the base is a heat pipe or a copper column, and the base includes plastic, metal, alloy or nonmetallic materials.

10. The heat dissipation apparatus as claimed in claim 1, wherein the heat dissipation apparatus is applied to a heat dissipation module for an electrical device and the heat dissipation apparatus is variably shaped related to a shape of the electrical device.

11. The heat dissipation apparatus as claimed in claim 10, wherein the heat dissipation module comprises a fan and the electrical device is a microprocessor or a transistor.

12. A heat dissipation apparatus, comprising:
a base;
a heat sink disposed around the base; and
a support member having an opening and at least one protruding part surrounded the opening;
wherein the support member, being connected with the base in a predetermined site by the protruding parts, contacts and supports the heat sink.

13. The heat dissipation apparatus as claimed in claim 12, wherein the protruding parts and the support member are integrally formed.

14. The heat dissipation apparatus as claimed in claim 12, wherein when the base passes through the opening and the protruding part are disposed in the predetermined site, the protruding parts become deformed to be engaged with the base by a force.

15. The heat dissipation apparatus as claimed in claim 12, wherein the base comprises a groove in the predetermined site for allowing the protruding parts be inserted thereinto.

16. The heat dissipation apparatus as claimed in claim 15, wherein when the protruding parts are inserted into the groove, the protruding parts become deformed to be engaged with the base by a force.

17. The heat dissipation apparatus as claimed in claim 15, wherein the protruding parts substantially protrude inwardly into the opening so that the support member is engaged with the base when the protruding parts are inserted into the groove.

18. The heat dissipation apparatus as claimed in claim 12, wherein the base is a heat pipe or a copper column, and the base includes plastic, metal, alloy or nonmetallic materials.

19. The heat dissipation apparatus as claimed in claim 12, wherein the heat dissipation apparatus is applied to a heat dissipation module for an electrical device and the heat dissipation apparatus is variably shaped related to a shape of the electrical device.

20. The heat dissipation apparatus as claimed in claim 19, wherein the heat dissipation module comprises a fan and the electrical device is a microprocessor or a transistor.
